(19) United States
(12) Patent Application Publication
(10) Pub. No.: US 2017/0271453 A1
(43) Pub. Date: Sep. 21, 2017

(54) SEMICONDUCTOR DEVICE AND METHOD OF MANUFACTURING THE SAME

(71) Applicant: SII Semiconductor Corporation, Chiba-shi (JP)

(72) Inventors: Keisuke NAGAO, Chiba-shi (JP); Takeshi MORITA, Chiba-shi (JP)

(21) Appl. No.: 15/459,548

(22) Filed: Mar. 15, 2017

(30) Foreign Application Priority Data
Mar. 16, 2016 (JP) 2016-052841

(51) Int. Cl. H01L 29/10; H01L 27/02; H01L 29/66; H01L 29/78; H01L 29/06

(52) U.S. Cl. CPC H01L 29/1095; H01L 29/7816; H01L 29/0653; H01L 29/66681; H01L 27/0266

(57) ABSTRACT

Provided is a semiconductor device including a second conductivity type low-concentration diffusion layer (101) for an electric field relaxation reaching a lower portion of a gate oxide film so as to cover a drain diffusion layer (107), in which a second conductivity type medium-concentration diffusion layer (102) is formed within the second conductivity type low-concentration diffusion layer (101) for the electric field relaxation, and a second conductivity type high-concentration diffusion layer (103), which has a high concentration and small variation in structure due to suppression of heat treatment as much as possible, is formed within the second conductivity type medium-concentration diffusion layer (102).

### RELATED APPLICATIONS

This application claims priority under 35 U.S.C. §119 to Japanese Patent Application No. 2016-052841 filed on Mar. 16, 2016, the entire content of which is hereby incorporated by reference.

### BACKGROUND OF THE INVENTION

1. Field of the Invention

The present invention relates to a semiconductor device, and more particularly, to a structure of a high-breakdown-voltage semiconductor device.

2. Description of the Related Art

In high-breakdown-voltage semiconductor devices, in recent years, a margin between an actual use voltage and a breakdown voltage has been reduced due to a tendency of reduction in area. In particular, a breakdown voltage of an ESD protection element, for example, an off transistor which is arranged such that a gate thereof is always turned off, needs to be set higher than the maximum operating voltage and lower than a breakdown voltage of an internal element. However, along with the margin reduction, a desired breakdown voltage is difficult to be obtained.

Further, in order to secure the reliability, the ESD protection element needs to have a high ESD resistance, that is, to be prevented from being damaged even when having a low resistance and a large amount of current flows. One of countermeasures which can easily be taken in order to obtain the high ESD resistance includes increasing a W length being a channel width of a transistor. However, at this time, the area is disadvantageously increased, thereby causing an increase in cost.

One example of such countermeasures is illustrated in FIG. 9. In this example, a second conductivity type medium-concentration diffusion layer 102 is formed around a drain diffusion layer 107 of the transistor in order to reduce a concentration of impurities in the vicinity of a P/N junction on a drain side which is formed of a P-type substrate 100 and a low-concentration diffusion layer 101 of the drain, and to increase a concentration of impurities in the vicinity of the drain diffusion layer 107. The concentration of impurities in the vicinity of the P/N junction on the drain side determines the breakdown voltage. Through formation of a double diffusion region, the transistor is devised so as to have the high breakdown voltage and low on resistance (see, for example, Japanese Patent Application Laid-open No. 2007-266473).

In general, when a diffusion layer having a high concentration is formed in the vicinity of a channel, an electric field at a channel end is increased so that the breakdown voltage is reduced. Thus, for the purpose of the high breakdown voltage, the diffusion layer having a high concentration needs to be formed so as to be away from the channel. With this structure, a length in an L direction connecting a source and the drain of the transistor is increased, with the result that the area is increased.

When the transistor, which has the double diffusion layer and is provided as one example of the countermeasures, is used as the off transistor, the structure of the diffusion layer needs to be adjusted so that the breakdown voltage may fall within a desired breakdown voltage range. A distance between the channel and the diffusion layer having a high concentration, or a distance between an end of the diffusion layer having a high concentration in a channel direction and a contact affects the breakdown voltage. It is difficult to manufacture an ESD protection element which is capable of protecting the internal element with a margin because the breakdown voltage sensitively changes in accordance with a small change in structure of the diffusion layer or process.

### SUMMARY OF THE INVENTION

In view of the above-mentioned description, the present invention has an object to provide a semiconductor device having a sufficient breakdown voltage and a sufficient ESD resistance without increasing a channel width.

A semiconductor device according to one embodiment of the present invention has a structure described below.

In the semiconductor device including: a first conductivity type semiconductor substrate; a gate electrode formed on the semiconductor substrate through intermediation of a gate oxide film; a second conductivity type source diffusion layer and a second conductivity type drain diffusion layer formed on respective sides of the gate electrode on the semiconductor substrate; and a second conductivity type low-concentration diffusion layer for an electric field relaxation reaching a lower portion of the gate oxide film so as to cover the drain diffusion layer, a second conductivity type medium-concentration diffusion layer is formed within the second conductivity type low-concentration diffusion layer for the electric field relaxation, and a second conductivity type high-concentration diffusion layer, which has a high concentration and small variation in structure due to suppression of heat treatment as much as possible, is formed within the second conductivity type medium-concentration diffusion layer.

According to the above-mentioned measures, since a concentration gradient can be formed in a stepwise manner from the channel toward the drain diffusion layer, a concentration of impurities in the vicinity of the channel can be reduced, and the concentration of impurities in the vicinity of the drain diffusion layer can be increased as compared to the related art. The electric field in the vicinity of the channel can be thereby relaxed to increase the breakdown voltage, and the high ESD resistance can be obtained by the reduction of the resistance in the vicinity of the drain diffusion layer.

Further, since concentration of high impurity concentration regions in the vicinity of the drain diffusion layer provides a margin for the breakdown voltage, a length in an L-length direction of the electric field relaxation layer can be reduced. Along with this, a margin for the ESD resistance is provided because resistance of a portion in the vicinity of the drain is low. Thus, a length in a W direction being the channel width of the transistor, which was set large in the related art, can be reduced. The area of the transistor can, consequently, be reduced.

Further, heat treatment is not performed so much on the second conductivity type high-concentration diffusion layer for the electric field relaxation so that the variation in structure by diffusion can be suppressed, with the result that the off transistor having the margin for the breakdown voltage can be designed.

### BRIEF DESCRIPTION OF THE DRAWINGS

FIG. 1 is a schematic sectional view for illustrating an N-type MOS transistor being a first embodiment of a semiconductor device according to the present invention.

FIG. 2 is a schematic sectional view for illustrating a P-type MOS transistor being a second embodiment of a semiconductor device according to the present invention.

FIG. 3 is a schematic sectional view for illustrating an N-type MOS transistor being a third embodiment of a semiconductor device according to the present invention.

FIG. 4 is a schematic sectional view for illustrating an N-type MOS transistor being a fourth embodiment of a semiconductor device according to the present invention.

FIG. 5A is a schematic sectional view for illustrating a process of manufacturing the N-type MOS transistor being the first embodiment of a semiconductor device according to the present invention.

FIG. 5B is a schematic sectional view for illustrating a process of manufacturing the N-type MOS transistor being the first embodiment of a semiconductor device according to the present invention, which is subsequent to FIG. 5A.

FIG. 6A is a schematic sectional view for illustrating a process of manufacturing the N-type MOS transistor being the first embodiment of a semiconductor device according to the present invention, which is subsequent to FIG. 5B.

FIG. 6B is a schematic sectional view for illustrating a process of manufacturing the N-type MOS transistor being the first embodiment of a semiconductor device according to the present invention, which is subsequent to FIG. 6A.

FIG. 7A is a schematic sectional view for illustrating a process of manufacturing the N-type MOS transistor being the first embodiment of a semiconductor device according to the present invention, which is subsequent to FIG. 6B.

FIG. 7B is a schematic sectional view for illustrating a process of manufacturing the N-type MOS transistor being the first embodiment of a semiconductor device according to the present invention, which is subsequent to FIG. 7A.

FIG. 8 is a schematic sectional view for illustrating a process of manufacturing the N-type MOS transistor being the first embodiment of a semiconductor device according to the present invention, which is subsequent to FIG. 7B.

FIG. 9 is a schematic sectional view for illustrating an example of an N-type MOS transistor manufactured by a related-art method.

### DETAILED DESCRIPTION OF THE PREFERRED EMBODIMENTS

Now, with reference to the drawings, modes for carrying out the present invention are described through embodiments.

### First Embodiment

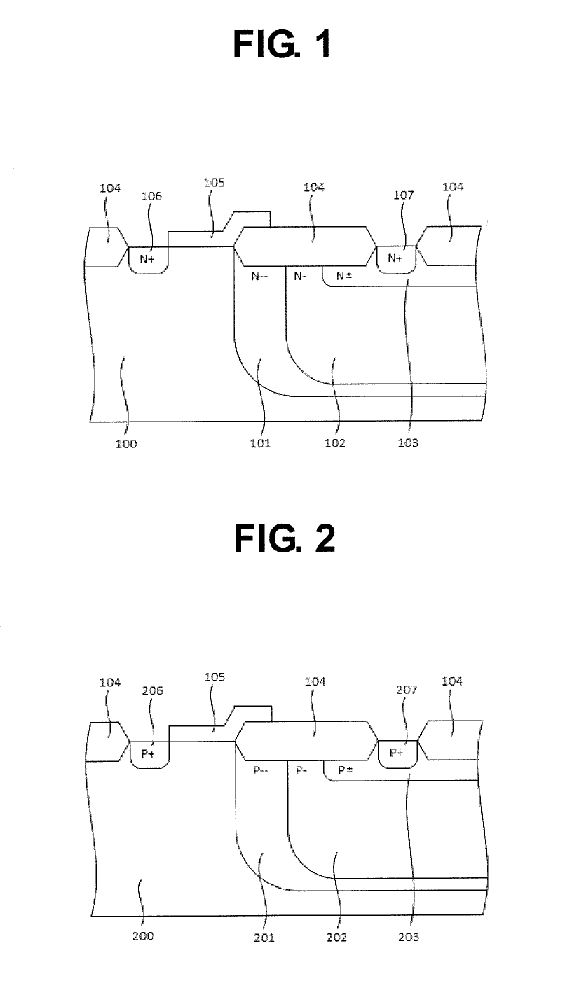

FIG. 1 is a schematic sectional view for illustrating an N-type MOS transistor for a first embodiment of a semiconductor device according to the present invention.

The N-type MOS transistor of the first embodiment is constructed by a first conductivity type semiconductor substrate 100, a gate electrode 105, a second conductivity type source diffusion layer 106, a second conductivity type drain diffusion layer 107, a second conductivity type low-concentration diffusion layer 101 for an electric field relaxation, a second conductivity type medium-concentration diffusion layer 102 for the electric field relaxation, and a second conductivity type high-concentration diffusion layer 103 for the electric field relaxation. The gate electrode 105 is formed on the semiconductor substrate 100 through intermediation of a gate oxide film (not shown). The second conductivity type source diffusion layer 106 and the second conductivity type drain diffusion layer 107 are formed on respective sides of the gate electrode 105 on the semiconductor substrate, and the drain diffusion layer 107 is formed through intermediation of a LOCOS oxide film 104. The second conductivity type low-concentration diffusion layer 101 is formed to reach a lower portion of the gate oxide film so as to cover the drain diffusion layer 107. The second conductivity type medium-concentration diffusion layer 102 is formed within the second conductivity type low-concentration diffusion layer 101. The second conductivity type high-concentration diffusion layer 103 is formed within the second conductivity type medium-concentration diffusion layer 102. The source diffusion layer 106 and the drain diffusion layer 107 are regions in which the impurities are diffused at a high concentration, and generally used as a region to be connected to wiring.

Symbols such as N−−, N−, N+, N+, P−−, P−, P+, and P+, which are used in the drawings, indicate a relative degree of concentration of the diffused impurities. That is, a concentration of N-type impurities is higher in N−−, N−, N±, N+ order, and a concentration of P-type impurities is higher in P−−, P−, P±, P+ order.

According to the above-mentioned structure, since a concentration gradient can be formed in a stepwise manner from the channel toward the drain diffusion layer, the concentration of impurities in the vicinity of the channel can be reduced, and the concentration of impurities in the vicinity of the drain diffusion layer can be increased as compared to the related art. The electric field in the vicinity of the channel can be thereby relaxed to increase the breakdown voltage, and the high ESD resistance can be obtained by the reduction of the resistance in the vicinity of the drain diffusion layer.

Further, since concentration of high impurity concentration regions in the vicinity of the drain diffusion layer provides a margin for the breakdown voltage, a length in an L-length direction of the electric field relaxation layer can be reduced. Along with this, a margin for the ESD resistance is provided because resistance of a portion in the vicinity of the drain is low. Thus, a length in a W direction being the channel width of the transistor, which was set large in the related art, can be reduced. The area of the transistor can, consequently, be reduced.

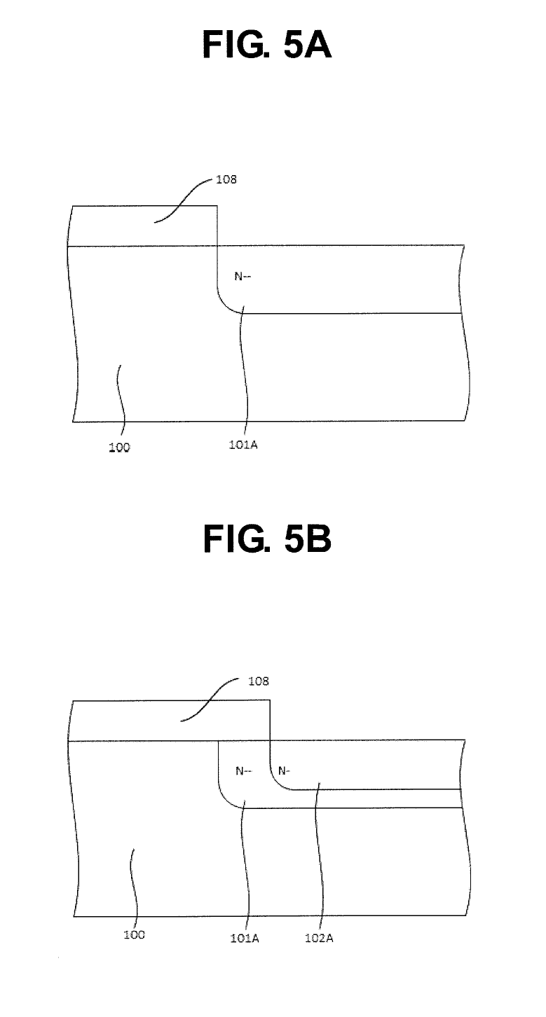

Next, description is made of a method of manufacturing the N-type MOS transistor of the first embodiment. FIG. 5A to FIG. 8 are schematic sectional views for illustrating a process of manufacturing the N-type MOS transistor of the first embodiment.

First, as illustrated in FIG. 5A, an N-type region 101A is formed by ion-implanting the N-type impurities while, for example, a resist film 108 formed on the P-type semiconductor substrate 100 is used as a mask.

Subsequently, after the resist film 108 is removed, the resist film 108 is formed so that an inner side of the N-type region 101A is opened as illustrated in FIG. 5B. Through use of the resist film 108 as a mask, the N-type impurities are ion-implanted so that an N-type region 102A is formed.

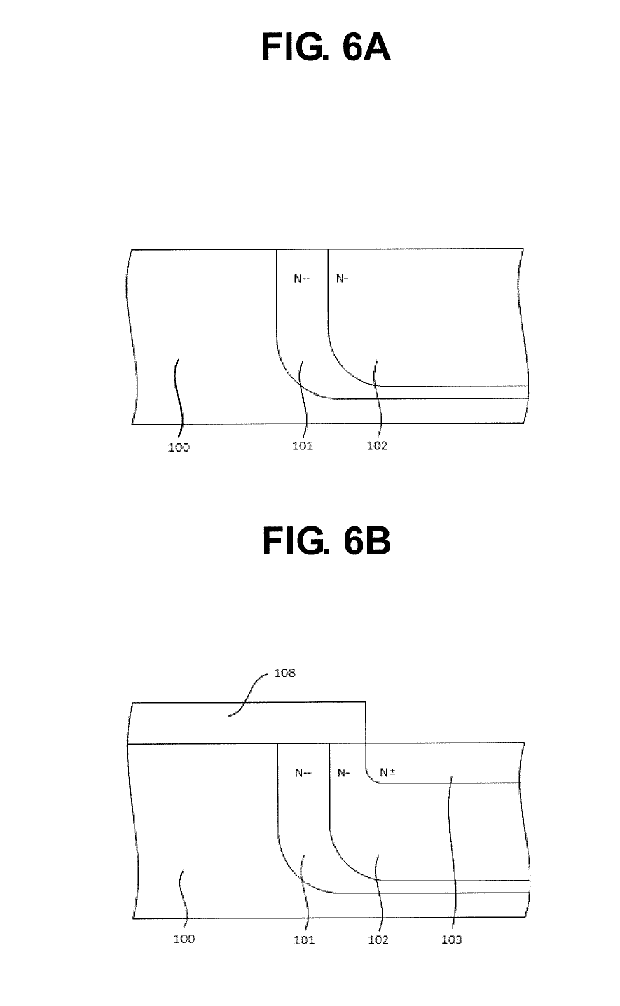

Subsequently, the N-type low-concentration diffusion layer 101 and the N-type medium-concentration diffusion layer 102 are formed as illustrated in FIG. 6A by diffusing the N-type region 101A and the N-type region 102A after the resist film 108 is removed.

Subsequently, as illustrated in FIG. 6B, the resist film 108 is formed so that an inner side of the N-type medium-concentration diffusion layer 102 is opened. Through use of the resist film 108 as a mask, the N-type impurities are ion-implanted so that the N-type high-concentration diffusion layer 103 is formed. The N-type low-concentration diffusion layer 101 and the N-type medium-concentration diffusion layer 102, which are also used as a well, have a wide diffusion area with a low-concentration. In contrast to this, absence of high-temperature and long-term heat treatment for diffusion of a well on the N-type high-concentration diffusion layer 103 permits formation of the high-concentration diffusion layer with small variation which is caused by the heat treatment. The breakdown voltage of the MOS transistor is greatly varied depending on a distance between the N-type high-concentration diffusion layer 103 and the channel, and a distance between an end of the N-type high-concentration diffusion layer 103 and the contact positioned in the drain diffusion layer 107. Thus, formation of the N-type high-concentration diffusion layer 103, in which variation in structure is small, is particularly effective when the off transistor having small breakdown voltage margin with an internal element is manufactured.

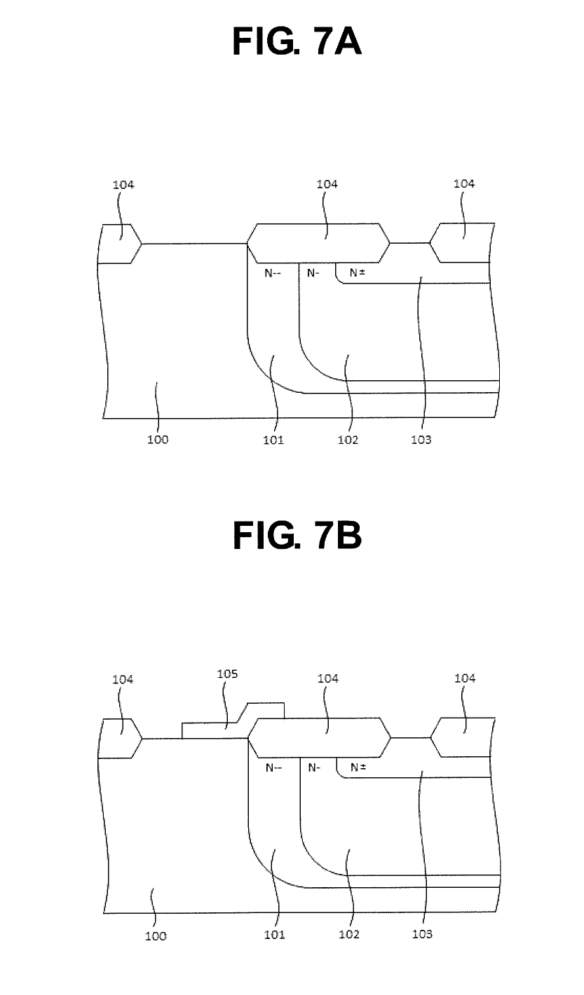

Subsequently, after the resist film 108 is removed, the LOCOS oxide film 104 is formed as illustrated in FIG. 7A by forming a nitride film being an anti-oxidation film at portions to be the source, the drain diffusion layer, and the channel, and then oxidizing a surface of the substrate.

Subsequently, after forming the gate oxide film (not shown), the gate electrode 105 is formed so as to overlap the portion to be the channel and the LOCOS oxide film 104 to be held in contact with the channel as illustrated in FIG. 7B.

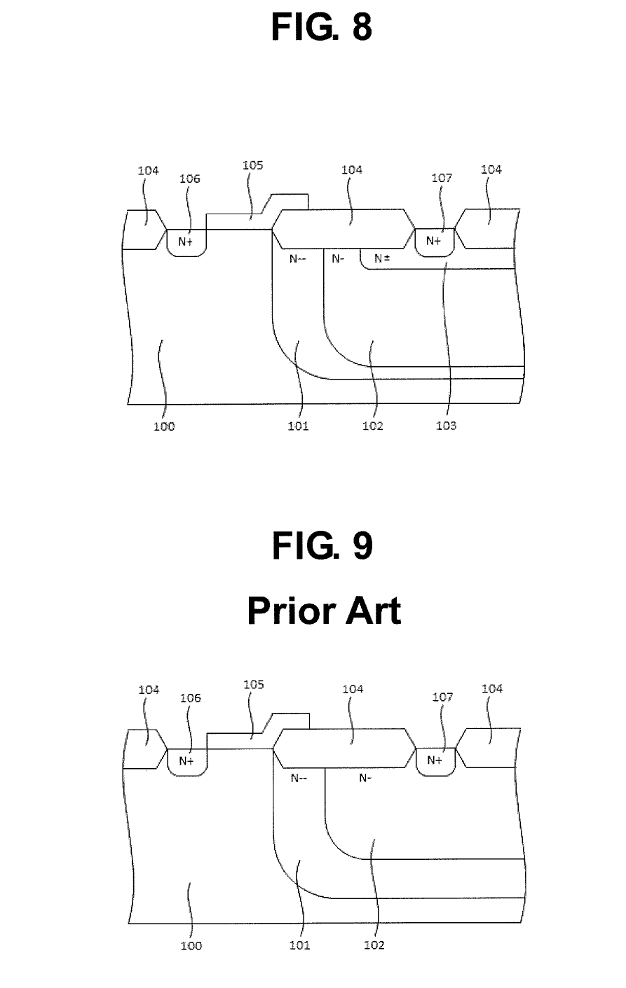

Subsequently, as illustrated in FIG. 8, the source diffusion layer 106 and the drain diffusion layer 107 are formed while the LOCOS oxide film 104 and the gate electrode 105 are used as a mask.

Although illustrations of the following steps are omitted, the semiconductor device is completed by forming the contact through insertion of an interlayer insulating film into the gate electrode 105, the source diffusion layer 106, and the drain diffusion layer 107, and by forming a metallic wiring and a passivation film.

As apparent from the manufacturing steps described above, the heat treatment is not performed so much on the second conductivity type high-concentration diffusion layer for the electric field relaxation so that the variation in structure by diffusion can be suppressed, with the result that the off transistor having the margin for the breakdown voltage can be designed.

### Second Embodiment

FIG. 2 is a schematic sectional view for illustrating a P-type MOS transistor for a second embodiment of a semiconductor device according to the present invention. The P-type MOS transistor is manufactured by reversing a polarity of the substrate of the first embodiment and a polarity of the diffused impurities.

The P-type MOS transistor is constructed by a second conductivity type semiconductor substrate 200, the gate electrode 105, a first conductivity type source diffusion layer 206, a first conductivity type drain diffusion layer 207, a first conductivity type low-concentration diffusion layer 201 for the electric field relaxation, a first conductivity type medium-concentration diffusion layer 202 for the electric field relaxation, and a first conductivity type high-concentration diffusion layer 203 for the electric field relaxation. The gate electrode 105 is formed on the semiconductor substrate 200 through intermediation of the gate oxide film (not shown). The first conductivity type source diffusion layer 206 and the first conductivity type drain diffusion layer 207 are formed on respective sides of the gate electrode 105 on the semiconductor substrate, and the drain diffusion layer 207 is formed through intermediation of the LOCOS oxide film 104. The first conductivity type low-concentration diffusion layer 201 is formed to reach the lower portion of the gate oxide film so as to cover the drain diffusion layer 207. The first conductivity type medium-concentration diffusion layer 202 is formed within the first conductivity type low-concentration diffusion layer 201. The first conductivity type high-concentration diffusion layer 203 is formed within the first conductivity type medium-concentration diffusion layer 202.

### Third Embodiment

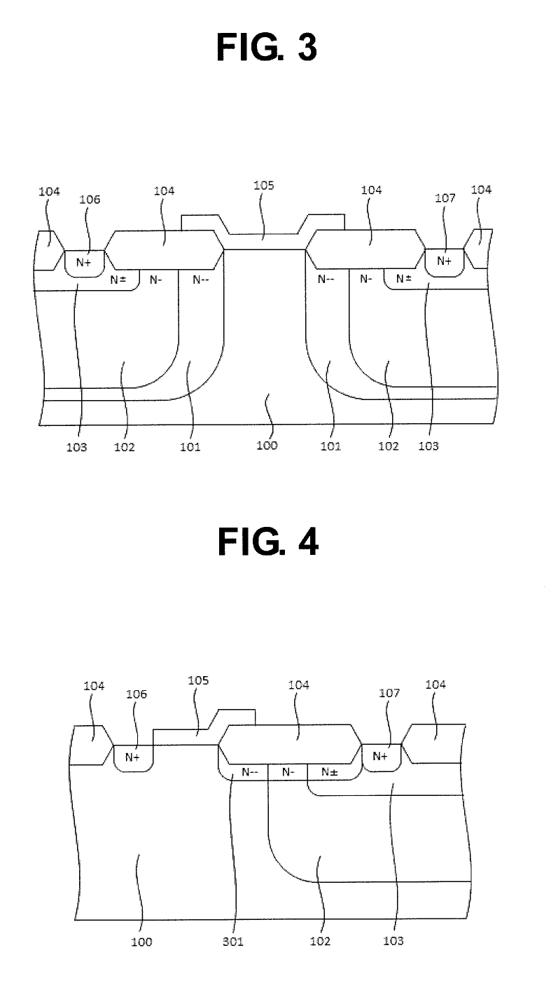

FIG. 3 is a schematic sectional view for illustrating an N-type MOS transistor for a third embodiment of a semiconductor device according to the present invention. The N-type MOS transistor is manufactured by forming, also on a source diffusion layer side, a second conductivity type low-concentration diffusion layer 101 for an electric field relaxation, a second conductivity type medium-concentration diffusion layer 102 for the electric field relaxation, and a second conductivity type high-concentration diffusion layer 103 for the electric field relaxation and the LOCOS oxide film 104 of the first embodiment that are positioned on a drain diffusion layer side.

With this manufacturing method, although an area of an element is increased, a semiconductor device acting similarly to the semiconductor device of the first embodiment can be obtained even when a potential of the source and a potential of the drain are reversed.

### Fourth Embodiment

FIG. 4 is a schematic sectional view for illustrating an N-type MOS transistor for a fourth embodiment of a semiconductor device according to the present invention.

The N-type MOS transistor of the fourth embodiment is constructed by the first conductivity type semiconductor substrate 100, the gate electrode 105, the second conductivity type source diffusion layer 106, the second conductivity type drain diffusion layer 107, a second conductivity type low-concentration diffusion layer 301 for the electric field relaxation, the second conductivity type medium-concentration diffusion layer 102, and the second conductivity type high-concentration diffusion layer 103. The gate electrode 105 is formed on the substrate 100 through intermediation of the gate oxide film (not shown). The second conductivity type source diffusion layer 106 and the second conductivity type drain diffusion layer 107 are formed on respective sides of the gate electrode 105 on the substrate, and the drain diffusion layer 107 is formed through intermediation of the LOCOS oxide film 104. The second conductivity type low-concentration diffusion layer 301 is formed so as to be held in contact with the drain diffusion layer 107 and reach the lower portion of the gate oxide film. The second conductivity type medium-concentration diffusion layer 102 is formed so as to cover the drain diffusion layer 107 from a portion between the drain diffusion layer 107 and the channel. The second conductivity type high-concentration diffusion layer 103 is formed within the second conductivity type medium-concentration diffusion layer 102.

The second conductivity type low-concentration diffusion layer 301 is formed by implanting the impurities only under the LOCOS oxide film 104 while the nitride film, which is arranged at the source, the drain region, and the channel as the anti-oxidation film at the time of forming the LOCOS oxide film 104, is used as a mask.

In the above-mentioned manufacturing method, the nitride film is used as a mask to form the low-concentration diffusion layer. Thus, the mask, which is used in the first embodiment and is required to form the second conductivity type low-concentration diffusion layer 101, can be omitted.

What is claimed is:

1. A semiconductor device, comprising:
a first conductivity type semiconductor substrate;
a gate electrode formed on the semiconductor substrate through intermediation of a gate oxide film;
a second conductivity type source diffusion layer and a second conductivity type drain diffusion layer formed on respective sides of the gate electrode on the semiconductor substrate;
a second conductivity type low-concentration diffusion layer for an electric field relaxation formed to reach a lower portion of the gate oxide film so as to cover the second conductivity type drain diffusion layer;
a second conductivity type medium-concentration diffusion layer formed within the second conductivity type low-concentration diffusion layer for the electric field relaxation; and
a second conductivity type high-concentration diffusion layer formed within the second conductivity type medium-concentration diffusion layer.

2. A semiconductor device according to claim 1, wherein the second conductivity type high-concentration diffusion region comprises a diffusion region having a high concentration and small variation as compared to the second conductivity type low-concentration diffusion region and the second conductivity type medium-concentration diffusion region.

3. A semiconductor device according to claim 1, further comprising:
a second second-conductivity-type low-concentration diffusion layer for the electric field relaxation formed to reach the lower portion of the gate oxide film so as to cover the second conductivity type source diffusion layer;
a second second-conductivity-type medium-concentration diffusion layer formed within the second second-conductivity-type low-concentration diffusion layer for the electric field relaxation; and
a second second-conductivity-type high-concentration diffusion layer formed within the second second-conductivity-type medium-concentration diffusion layer.

4. A semiconductor device, comprising:
a first conductivity type semiconductor substrate;
a gate electrode formed on the semiconductor substrate through intermediation of a gate oxide film;
a second conductivity type source diffusion layer and a second conductivity type drain diffusion layer formed on respective sides of the gate electrode on the semiconductor substrate, the second conductivity type drain diffusion layer being formed through intermediation of a LOCOS oxide film;
a second conductivity type low-concentration diffusion layer for an electric field relaxation so as to be held in contact with the second conductivity type drain diffusion layer and reach a lower portion of the gate oxide film;
a second conductivity type medium-concentration diffusion layer formed so as to cover the second conductivity type drain diffusion layer from a portion between the second conductivity type drain diffusion layer and a channel; and
a second conductivity type high-concentration diffusion layer formed within the second conductivity type medium-concentration diffusion layer.

5. A semiconductor device according to claim 4, wherein the second conductivity type low-concentration diffusion layer for the electric field relaxation is formed only under the LOCOS oxide film.

6. A method of manufacturing a semiconductor device,
the semiconductor device comprising:
a first conductivity type semiconductor substrate;
a gate electrode formed on the semiconductor substrate through intermediation of a gate oxide film;
a second conductivity type source diffusion layer and a second conductivity type drain diffusion layer formed on respective sides of the gate electrode on the semiconductor substrate;
a second conductivity type low-concentration diffusion layer for an electric field relaxation formed to reach a lower portion of the gate oxide film so as to cover the second conductivity type drain diffusion layer;
a second conductivity type medium-concentration diffusion layer formed within the second conductivity type low-concentration diffusion layer for the electric field relaxation; and
a second conductivity type high-concentration diffusion layer formed within the second conductivity type medium-concentration diffusion layer,
the method comprising:
forming the second conductivity type low-concentration diffusion layer and the second conductivity type medium-concentration diffusion layer; and
forming the second conductivity type high-concentration diffusion layer,
the step of forming the second conductivity type high-concentration diffusion layer being performed after the step of forming the second conductivity type low-concentration diffusion layer and the second conductivity type medium-concentration diffusion layer.
